(19) United States
(12) Patent Application Publication
(10) Pub. No.: US 2026/0190387 A1
(43) Pub. Date: Jul. 2, 2026

(54) TRANSISTOR WITH LINER-LAST SOURCE AND DRAIN TRENCH CONTACTS, AND METHODS OF MAKING SAME

(71) Applicant: Intel Corporation, Santa Clara, CA (US)

(72) Inventors: Nazila Haratipour, Portland, OR (US); Nancy Zelick, Portland, OR (US); Wenshen Li, Fremont, CA (US); Christopher Jezewski, Portland, OR (US); Jiun-Ruey Chen, Hillsboro, OR (US); Gilbert Dewey, Beaverton, OR (US); Manish Chandhok, Beaverton, OR (US)

(73) Assignee: Intel Corporation, Santa Clara, CA (US)

(21) Appl. No.: 19/002,679

(22) Filed: Dec. 26, 2024

(51) Int. Cl. H10D 30/67; H10D 30/00; H10D 30/01; H10D 30/47; H10D 62/10; H10D 84/01; H10D 84/83

(52) U.S. Cl. CPC H10D 30/6729; H10D 30/017; H10D 30/019; H10D 30/47; H10D 30/501; H10D 30/6735; H10D 62/118; H10D 84/0128; H10D 84/0149; H10D 84/832; H10D 84/834

(57) ABSTRACT

Semiconductor devices and systems with liner-last trench contacts, and methods of forming the same. The semiconductor device comprises a source region and a drain region, a source trench contact coupled to the source region, and a drain trench contact coupled to the drain region. Each trench contact resides in a contact trench and includes a contact plug, a contact metal layer below the contact plug, and a trench liner at the sidewalls of the contact trench. The uppermost surface of the contact metal layer is below the lowermost surface of the trench liner. A channel couples the source region to the drain region, and a gate couples to the channel. The trench liner includes silicon and at least one of oxygen and carbon. The device may correspond to a nanoribbon transistor, a gate-all-around (GAA) transistor, a fin field-effect transistor (FinFET), a planar transistor, or a two-dimensional transistor.

### BACKGROUND

Current transistors involve the use of trench contacts coupled to the source regions and to the drain regions of such transistors. Individual ones of the trench contacts typically include a contact plug, a contact metal layer under the contact plug, and a trench liner. The trench liner often includes silicon nitride, and serves to isolate the electrically conductive contact plug and contact metal layer from the surrounding components of a transistor, including the gate. The process of forming these trench contacts requires precise engineering to ensure optimal performance and reliability of the semiconductor devices.

### BRIEF DESCRIPTION OF THE DRAWINGS

FIG. 1A illustrates an example of a transistor.

FIG. 1B illustrates an example of a transistor according to one embodiment.

FIGS. 2A-2G illustrate various stages of fabrication of a transistor similar to the transistor of FIG. 1B.

FIG. 3 illustrates a cross-section of an example integrated circuit according to some embodiments.

FIG. 4 is a top view of a wafer and dies that may be included in a microelectronic assembly.

FIG. 5 is a cross-sectional side view of an integrated circuit device that may be included in a microelectronic assembly.

FIGS. 6A-D are perspective views of example planar, FinFET, gate-all-around, and stacked gate-all-around transistors.

FIG. 7 is a cross-sectional side view of an integrated circuit device assembly that may include a microelectronic assembly.

FIG. 8 is a block diagram of an example electrical device that may include a microelectronic assembly.

FIG. 9 illustrates a flowchart for forming an integrated circuit with liner-last trench contacts.

### DETAILED DESCRIPTION

The semiconductor industry continually seeks to enhance the performance and efficiency of semiconductor devices, particularly transistors. Transistors serve as building blocks in various electronic devices, including integrated circuits, microprocessors, and memory devices. The demand for higher speed, lower power consumption, and increased device density drives the need for innovative transistor designs and fabrication methods. One aspect of transistor performance is the contact resistance between the source/drain regions and the corresponding contact metal layers. Reducing this contact resistance is for improving the overall performance of the transistor. Current solutions in the semiconductor industry involve the use of trench contacts to connect the source/drain regions to the contact metal layers. These trench contacts typically include a contact metal plug, a contact metal layer, and a trench liner. The trench liner, often made of silicon nitride, serves to isolate the contact metal from the surrounding materials and prevent shorting. The process of forming these trench contacts presents several challenges. The need to etch through the trench liner to expose the source/drain regions can lead to thinning of the trench liner, which increases the risk of capacitance between the gate contact and the contact metal layer. This increased capacitance can degrade the performance of the transistor by slowing down the operation of the transistor.

Some embodiments seek to address these challenges by providing a novel semiconductor device and method of fabrication that improves the contact resistance and reduces the capacitance between the gate contact and the contact metal layer. The semiconductor device comprises a source region, a drain region, a source trench contact, a drain trench contact, a channel coupling the source region to the drain region, and a gate coupled to the channel. The source and drain trench contacts include a contact plug, a contact metal layer, and a trench liner. The contact metal layer is positioned below the trench liner, and the uppermost surface of the contact metal layer is below the lowermost surface of the trench liner. This configuration enhances the contact area between the contact metal layer and the source/drain regions, thereby reducing contact resistance. Additionally, the trench liner is selectively deposited to avoid the need for etching through the liner, which minimizes the risk of capacitance increase and improves the overall performance of the transistor.

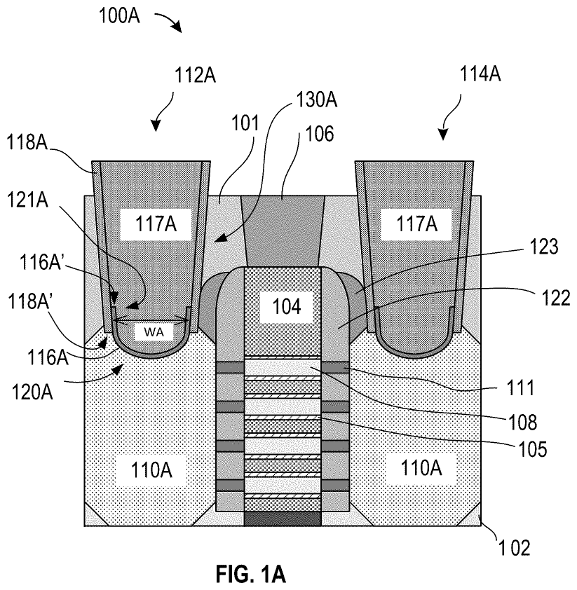

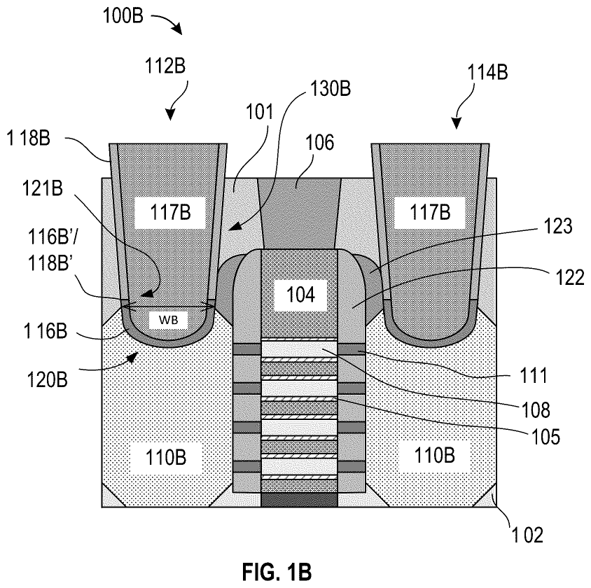

FIG. 1A illustrates an example of a transistor 100A. Transistor 100A may be part of a semiconductor device such as an integrated circuit. Transistor 100A can be either a PMOS or NMOS transistor.

In the illustrated embodiment, the transistor 100A is a nanoribbon transistor, where nanoribbons 108 are used as the transistor channel. In particular, the transistor 100A includes source/drain regions 110A formed over a substrate 102, nanoribbons 108 extending between the source/drain regions 110A, and a gate 104 formed around the nanoribbons 108. The nanoribbons 108 couple the source/drain regions 110A and serve as the channel of the transistor 100A. The tips/ends 111 of the nanoribbons 108 are doped with the same dopants as the source/drain regions 110A, which causes the source/drain regions 110A to effectively extend or protrude into the tips 111 of the nanoribbons 108. The gate 104 includes an associated gate oxide 105 formed around the nanoribbons 108 (e.g., between the gate 104 and the nanoribbons 108 to provide separation), along with an associated gate contact 106 formed over/above the gate 104. The source/drain regions 110A include source/drain trench contacts (or trench contacts) 114A, 112A, each of which includes a contact metal layer 116A, a contact plug 117A, and a contact trench liner 118A. The remaining areas are filled with an inter-layer dielectric (ILD) 101 (e.g., an isolation oxide). The first spacer 122 and the second spacer or gate trench fill 123 flank the gate 104, with the second spacer 123 including a relatively low resistance fill metal that facilitates easy access to the gate. The second spacer 123 may include a work function metal that sets the threshold voltage of the transistor.

Source/drain regions 110A include a doped epitaxial semiconductor material. Source/drain contact recess 120A is defined within the epitaxial source/drain regions 110A. The source/drain contact recess 120A houses the contact metal layer 116A, and is part of the contact trench 130A. The contact trench 130A is thus to house the source/drain trench contacts 112A and 114A.

Contact metal layers 116A of source/drain trench contacts 112A and 114A are to facilitate current flow from the source region to the drain region (it being noted that trench contact 112A could be a trench contact of a source region or a drain region, and trench contact 114A could be a trench contact for a drain region or a source region).

The contact metal layer 116A is concave-shaped, matching the shape of source/drain contact recess 120A. The contact metal layer 116A nests within the sidewalls of the trench liner 118A at the nesting region 121A. The uppermost surface 116A′ of the contact metal layer 116A extends above the lowermost surface 118A′ of the trench liner 118A. The width WA of the contact metal layer 116A is, disadvantageously, limited by the thickness of the trench liner 118A at the nesting region 121A.

The contact metal layer 116A can be deposited using techniques such as atomic layer deposition (ALD), chemical vapor deposition (CVD), or physical vapor deposition (PVD).

In the configuration of FIG. 1A, in order to form the trench contacts 112A/114A, trench 130A is first formed in ILD 101 by way of an etch process. Thereafter, the material for the trench liner 118A, silicon nitride, is deposited within trench 130A, and then etched down directionally such that the trench liner 118A remains on sidewalls of trench 130A, while the material of the trench liner is etched away at the bottom of trench 130A, “punching through” the silicon nitride and forming recess 120A as part of trench 130A. Thereafter, contact metal layer 116A is formed within recess 120A. Thereafter, the remaining trench is filed with the contact trench metal, which could, for example, include tungsten, to form contact plug 117A, thereby completing the formation of source/drain trench contacts 112A/114A.

Because, in the state of the art, the trench liner 118A is formed first, the contact metal layer 116A will, together with the bottom portion of trench liner 118A, define nesting region 121A. Nesting region 121A limits the width WA of the contact metal layer, disadvantageously reducing the surface area of contact between the contact metal layer 116A and the underlying source/drain region. In addition, the directional etch process used on the material of the trench liner 118A can attack/damage the same, leading to thinning of the trench liner during formation. Silicon nitride is routinely used for trench liners because of its durability or resistance to etches in a given direction. However, its durability and the related directionality of the etch are not perfect, hence the thinning issue. A thinning of trench liner 118A tends to increase capacitance between the gate contact 106 and the contact metal layer 116A, potentially slowing down the transistor.

Some embodiments involve forming a contact metal layer of a source/drain region of a transistor before forming a trench liner lining the associated contact trench.

Some embodiments include a transistor where the trench liner includes at least one of oxygen and carbon.

Some embodiments include a transistor where the trench liner includes a selective dielectric material (e.g., an oxide material that is selective to deposition on a dielectric material and not on a metal).

Some embodiments provide a process of making a transistor that includes depositing the material of the trench liner directly onto a dielectric material at sidewalls of the contact trench without depositing such material on a surface of the corresponding contact metal. Such process embodiments advantageously avoid the need to etch through (or “punch through”) a material of the trench liner, avoiding a thinning of the same.

Some embodiments involve increasing the surface contact area between the contact metal layer and its corresponding source/drain region.

Reference is now made to FIG. 1B, which shows a nanowire transistor 100B according to an embodiment. Transistor 100B may be similar to transistor 100A, except for the configuration of its trench contacts 112B/114B, and the resultant configuration of surrounding structures, as will be explained in further detail below. For the latter reason, like component as between FIGS. 1A and 1B will be referred to herein with like reference numerals. In addition, for the same reason, a detailed description of such like components with respect to FIG. 1B may sometimes be omitted below.

Transistor 100B may further be similar to transistor 100A, in addition by virtue of material other than silicon nitride used for the trench liner 118B, for example a material that includes at least one of oxygen or carbon.

FIG. 1B thus shows an embodiment of a transistor 100B, which can be either a PMOS or NMOS transistor. The same process embodiment may thus be used for both PMOS and NMOS fabrication. The transistor 100B includes trench contacts 112B and 114B. Each trench contact 112B and 114B contains a contact plug 117B and a contact metal layer 116B. The contact metal layers 116B are situated under a trench liner 118B and do not nest within the same, but underly the same.

The epitaxial source/drain regions 110B include doped epitaxial semiconductor material. These regions define the source/drain contact recess 120B, which is located within the contact trench 130B. The contact trench 130B houses the contact metal layer 116B, which facilitates current flow from the source to the drain. The contact metal layer 116B is concave-shaped, has a width WB at its uppermost surface 116B′ that is as wide as a lowermost surface 118B′ of the trench liner 118B, in this manner increasing the surface area contact of the contact plug 117B with the source/drain region 110B by virtue of a wider contact metal layer 116B′ as compared with contact metal layer 116A of the state of the art.

The contact metal layer 116B does not nest within the trench liner 118B. Instead, the uppermost surface 116B′ of the contact metal layer 116B is below the lowermost surface 118B′ of the trench liner 118B, and, in the shown embodiment, defines an interface region 121B where uppermost surface 116B′ is adjacent lowermost surface 118B′, although embodiments are not limited to a structure where the uppermost surface 116B′ is adjacent to the lowermost surface 118B′. The width WB of the contact metal layer 116B is not limited by the trench liner 118B and corresponds to the width of the trench liner 118B at the interface region 121B. Therefore, the width WB of the contact metal layer 116B corresponds to a width of trench 130B at the interface region 121B. In the shown embodiment, width WB is wider than the width of the contact plug at the interface region 121B.

The contact metal layer 116B may be deposited using techniques such as atomic layer deposition (ALD), chemical vapor deposition (CVD), or physical vapor deposition (PVD). The concave shape of the contact metal layer 116B allows for more surface area contact between the contact metal layer and the corresponding source/drain region 110B, enhancing current flow efficiency.

The material of the trench liner 118B may include a “selective” dielectric material. The material of the trench liner 118B is “selective” as used herein in that its deposition process in trench 130B involves a deposition thereof that is selective to the dielectric material defining or lining sidewalls of trench 130B, and not to the epitaxial material of the source/drain regions 110B, and not to the metal of the contact metal layer 116B already deposited. In the shown embodiment, the selective dielectric material includes a material that is selective to the material of ILD 101 defining the sidewalls of trench 130B. Examples of the selective dielectric material for the trench liner 118B include, by way of example, one or more low-k liners, such as one or more of SiO₂, SiOC, SiOCH, SiOCHN, SiOCN, SiON, or SiC.

The selective dielectric material may include silicon and oxygen, silicon and carbon, silicon, oxygen, and carbon, silicon, oxygen, carbon, and hydrogen, silicon, oxygen, carbon, hydrogen, and nitrogen, silicon, oxygen, carbon, and nitrogen, silicon, oxygen, and nitrogen, or silicon and nitrogen. The dielectric constant ranges from 3.9 to 7 for these materials.

Because the trench liner 118B is selectively deposited, the thickness of the trench liner 118B may be controlled, allowing control of the capacitance between the gate 104 and the contact plug 117B. This can happen even though the trench liner may be thicker, at least at portions thereof, than trench liners of the state of the art. Additionally, a material of trench liner 118B may be chosen to have a lower dielectric constant to allow the capacitance from the contact metal layer 116B to the gate 104 to be lower than that of the state of the art.

The selective low-k dielectric material used for trench liner 118B, typically silicon oxycarbide or silicon dioxide (SiO2), has a reduced dielectric constant compared to stoichiometric silicon nitride, which has a dielectric constant of 8. By adding oxygen or carbon to silicon nitride, the effective dielectric constant of the thus formed material is lowered, decreasing the capacitance between the metal in the trench contacts 112B and 114B and the gate 104. This results in improved performance by reducing electrical interference.

Some embodiments involve growing the material of the trench liner 118B on dielectric sidewalls of the trench 130B, which may include oxide and/or nitride sidewalls, after formation of the contact metal layer 116B (hence the “liner-last trench contacts” as referred to herein). The material of the trench liner 118B would not grow on epitaxial silicon (EPI) or metal. This may be achieved, for example, by passivating surfaces of the metal material of the contact metal layer 116B, and/or of the EPI, with specific passivants prior to growing the trench liner 118B. The passivation prevents oxide precursors used in growing the trench liner 118B from attaching to the metal of the contact metal layer 116B. In this way, the material of the trench liner 118B grows on sidewalls of trench 130B, on top of uppermost surfaces of and not on contact metal layer 116B.

According to some embodiments, the passivant may include at least one of: one or more thiols, one or more aromatics, one or more amines, one or more alkynes, one or more nitriles, one or more phosphines, one or more phosphites, or one or more amidines. Thus, according to an embodiment, the passivant may include carbon and hydrogen. According to a variation, the passivant may include carbon, hydrogen, and one of sulfur, nitrogen, oxygen or phosphorus. According to a variation, the passivant may include carbon, hydrogen, oxygen, and phosphorus.

For example, the one or more thiols may include one or more of: 1-octanethiol, 1-decanethiol, or 1-dodecanethiol.

For example, the one or more aromatics may include one or more of aniline, piperidine, pyridine, benzene, or toluene.

For example, the one or more amines may include one or more of diethylamine, triethylamine, ethylenediamine, benzylamine, ammonia, or N,N′-dimethylhydrazine.

For example, the one or more alkynes may include one or more of acetylene, 2-butyne, 3-hexyne, 4-octyne, or phenylacetylene.

For example, the one or more nitriles may include one or more of acetonitrile, benzonitrile, or butyronitrile.

For example, the one or more phosphines and phosphites may include one or more of trimethylphosphine, triethylphosphine, or trimethylphosphite.

For example, the one or more amidines may include one or more of N,N-dimethylacetamidine or N,N-dimethylformamidine.

Method embodiments eliminate the need to etch through or punch through the material of the trench liner during the process of forming the source/drain contacts, simplifying fabrication and avoiding the creation of a nested “U-shaped” hollow in the trench.

The contact metal layer 116B aligns with outer edges of the trench liner 118B, maximizing the contact area with source/drain regions 110B without requiring the nesting configuration as seen by nesting region 121A of the state of the art. This improves the contact resistance without needing deeper etches into the epitaxial source/drain regions to increase contact metal layer surface area.

The trench liner 118B is deposited after the contact metal layer and passivation of the latter, allowing for precise thickness control of the trench liner 118B. The deposition of the trench liner 118B prevents shorting between the gate 104 and trench contacts 112B and 114B, reduces capacitance, and removes the dependency on needing to punch through the material of a silicon nitride trench liner to form the contact metal layer 116B.

Embodiments offer several advantages over the prior art. The increased contact width of the contact metal layer 116B reduces contact resistance and thus the need for aggressive, deep etching into the source/drain regions. By avoiding overly deep etching and trench liner removal operations, some embodiments avoid the risks of shorts or damage to nearby structures, thereby improving yield. The selective deposition of the material of the trench liner allows the trench liner to be tailored in thickness without affecting earlier steps, enhancing the design's adaptability.

The implementation steps for the new process include preparing the EPI by etching a trench into the oxide to expose the EPI, creating a curved hollow at the bottom. The contact metal layer is then deposited selectively after passivation, ensuring alignment with the trench's edges. The trench liner is deposited on the sidewalls using selective chemistry, utilizing the passivated areas to ensure no deposition on the metal or EPI. Finally, the process is completed with tungsten filling to finalize the structure.

Embodiment variations may include a double trench liner configuration (e.g., an inner silicon nitride trench liner and an outer silicon oxycarbide trench liner) for enhanced protection if required. Contact metal layer profiles can vary between slightly U-shaped or flatter, depending on process requirements.

Design considerations include the risks associated with deeper etching. While deeper etching into the epitaxial material of the source/drain regions increases contact area, it also widens the trench, reducing the margin between the trench and the gate. This can cause yield issues such as shorts. The “trench liner last” approach mitigates these risks by increasing contact area with a wider, shallower trench.

This streamlined approach not only simplifies manufacturing but also enhances device performance and reliability, making it a significant improvement over conventional methods. Advantageously, a lower capacitance leads to a more efficient transistor.

The materials used to form the respective layers may vary in different embodiments. Examples of materials that may be used for each layer are provided below.

The substrate 102 may be made of any suitable material(s), including, without limitation, silicon.

The inter-layer dielectric (ILD) 101, also referred to as an isolation oxide, may be made of any suitable dielectric material(s), including, without limitation, silicon dioxide (SiO2) (and/or other oxides of silicon), silicon oxynitride (SiON), and/or silicon oxycarbide (SiOC). Thus, in some embodiments, the ILD 101 may be made of material(s) that include elements such as silicon (Si), oxygen (O), nitrogen (N), and/or carbon (C).

The gate 104 may be made of any suitable conductive or metal material(s), including, without limitation, titanium (Ti), titanium nitride (TiN), aluminum (Al), titanium aluminide (TiAl), titanium aluminum nitride (TiAlN), titanium silicon nitride (TiSiN), nickel (Ni), platinum (Pt), molybdenum (Mo), and/or tungsten (W). Thus, in some embodiments, the gate 104 may be made of material(s) that include elements such as titanium (Ti), aluminum (Al), nickel (Ni), platinum (Pt), molybdenum (Mo), tungsten (W), nitrogen (N), and/or silicon (Si).

The gate oxide 105 may be made of any suitable dielectric material(s), including, without limitation, hafnium oxide (HfO2), silicon dioxide (SiO2) (or other oxides of silicon), silicon oxynitride (SiON), zirconium dioxide (ZrO2), lanthanum oxide (La2O3), tantalum pentoxide (Ta2O5), HfSiO2, ZrSiO2, and/or LaSiO2. Thus, in some embodiments, the gate oxide 105 may be made of material(s) that include elements such as hafnium (Hf), silicon (Si), oxygen (O), nitrogen (N), zirconium (Zr), lanthanum (La), and/or tantalum (Ta).

The gate contact 106 may be made of any suitable conductive or metal material(s), including, without limitation, cobalt (Co), tungsten (W), molybdenum (Mo), aluminum (Al), and/or copper (Cu).

The nanoribbons 108 may be made of any suitable material(s), including, without limitation, silicon (Si), germanium (Ge), and/or silicon germanium (SiGe) (e.g., with any Si-to-Ge ratio). Thus, in some embodiments, the nanoribbons 108 may be made of material(s) that include elements such as silicon (Si) and/or germanium (Ge).

The source/drain regions 110B (and doped nanoribbon tips 111) may be made of any suitable material(s), including, without limitation, doped silicon (Si) (e.g., phosphorous-doped Si, arsenic-doped Si) and/or doped silicon germanium (SiGe) (e.g., boron-doped SiGe with various percentages of Si and Ge). Thus, in some embodiments, the source/drain regions 110B (and doped nanoribbon tips 111) may be made of material(s) that include elements such as silicon (Si), germanium (Ge), phosphorous (P), arsenic (As), and/or boron (B).

The trench contacts 112A/B, 114A/B may be made of any suitable material(s), including those described below with respect to the contact metal 116A/B and contact plug 117A/B, although the material for trench liner 118A is different from that of embodiments as described by way of example in relation to trench liner 118B.

The trench contact metal 116A/B may be made of any suitable conductive or metal material(s), including, without limitation, titanium (Ti), titanium nitride (TiN), aluminum (Al), titanium aluminide (TiAl), nickel (Ni), platinum (Pt), molybdenum (Mo), tungsten (W), scandium (Sc), erbium (Er), yttrium (Y), ytterbium (Yb), gadolinium (Gd), terbium (Tb), and/or dysprosium (Dy). Thus, in some embodiments, the trench contact metal 116A/B may be made of material(s) that include elements such as titanium (Ti), aluminum (Al), nickel (Ni), platinum (Pt), molybdenum (Mo), tungsten (W), scandium (Sc), erbium (Er), yttrium (Y), ytterbium (Yb), gadolinium (Gd), terbium (Tb), dysprosium (Dy), and/or nitrogen (N).

The contact plug 117A/B may be made of any suitable conductive or metal material(s), including, without limitation, cobalt (Co), tungsten (W), molybdenum (Mo), aluminum (Al), and/or copper (Cu).

The contact trench liner 118A may be made of any suitable dielectric material(s), such as silicon nitride.

The contact trench liner 118B may include one or more low-k liners, such as one or more of SiO₂, SiOC, SiOCH, SiOCHN, SiOCN, SiON, or SiC. Contact trench liner 118B may include silicon nitride.

In various embodiments, transistor 100B may be implemented using other types, numbers, and/or arrangements of layers and materials than those shown and described with respect to FIG. 1B. For example, the size and/or materials of the layers may vary. Moreover, certain components of transistor 100A may be added, replaced, omitted, and/or rearranged. For example, the substrate 102 may not be present in some embodiments, as it may be completely grinded/thinned away during fabrication. Further, while transistor 100A is a nanoribbon transistor, liner-last trench contacts can be implemented on any type of transistor, including nanoribbon transistors, gate-all-around (GAA) transistors, fin field-effect transistors (FinFET), planar transistors, and two-dimensional (2D) transistors (e.g., made of 2D semiconductor materials), among others. In various embodiments, transistors with liner-last trench contacts may be used for power delivery or signaling on semiconductor devices such as integrated circuits.

Advantageously, the selective deposition of the trench liner material allows for precise control over the thickness of the trench liner material. This control enables the optimization of the trench liner's dielectric properties, further reducing capacitance and improving the transistor's efficiency. The use of materials with lower dielectric constants, such as silicon oxycarbide or silicon dioxide, contributes to this reduction in capacitance, leading to better electrical performance.

Advantageously, the increased contact area between the contact metal layer and the source/drain regions, achieved by avoiding the nesting configuration, results in lower contact resistance. This improvement in contact resistance enhances current flow efficiency, which is important for high-performance semiconductor devices. The wider contact metal layer also reduces the need for aggressive, deep etching into the source/drain regions, thereby minimizing the risk of shorts and damage to nearby structures.

Advantageously, the described process embodiments enhance yield by simplifying fabrication and reducing the likelihood of defects. By avoiding the need to punch through the trench liner material, the process mitigates the risks associated with deep etching and trench liner removal operations. This streamlined approach not only simplifies manufacturing but also enhances device reliability, making the process embodiments a significant improvement over conventional methods.

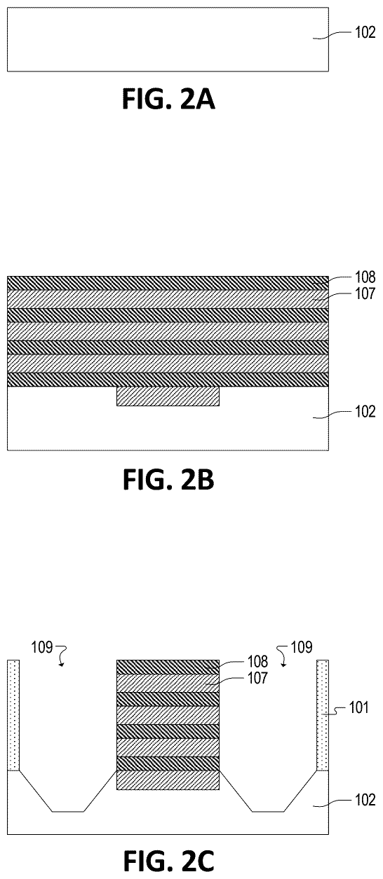

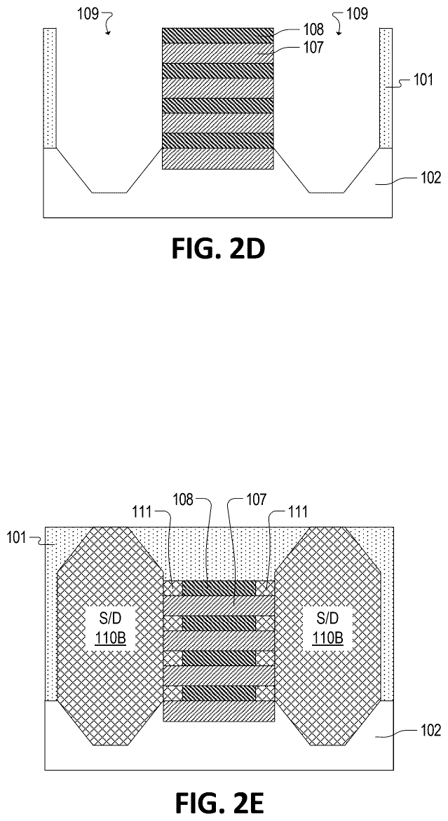

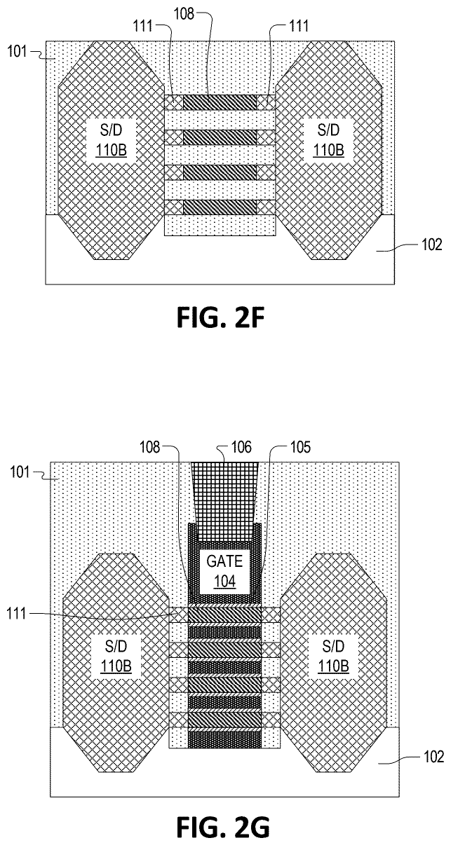

FIGS. 2A-G illustrate an example process flow for forming a transistor with liner-last trench contacts according to some embodiments. In the illustrated example, the process flow is used to form the transistor 100B of FIG. 1B. It will be appreciated in light of the present disclosure that the illustrated process flow is only one example methodology for arriving at a transistor with liner-last trench contacts.

In FIG. 2A, a substrate 102 is received. In some embodiments, the substrate 102 may be a silicon substrate.

In FIG. 2B, a superlattice with alternating silicon germanium (SiGe) 107 and silicon (Si) 108 layers is formed over the substrate 102. In the illustrated embodiment, the Si layers 107 are the nanoribbons that will serve as the channel of the transistor 100 once complete.

In FIG. 2C, the SiGe/Si superlattice layers 107, 108 are etched away in the areas 109 where the respective source/drain regions 110B will be formed.

In FIG. 2D, the source/drain regions 110B are epitaxially grown. Further, the tips 111 of the silicon nanoribbons 108 are doped, which effectively causes the source/drain regions 110B to extend into the nanoribbons 108.

In FIG. 2E, the SiGe layers 107 are removed (e.g., etched) to release the nanoribbons.

In FIG. 2F, the gate oxide 105, gate 104, and gate contact 106 are formed.

For example, the gate oxide/dielectric 105 is formed over/around the released nanoribbon channels 108, and the gate 104 is then formed over/around the gate oxide 105 and nanoribbon channels 108. The gate contact 106 is then formed above/over the gate 104.

Going back now to FIG. 1B, the trench contacts 112B and 114B are formed over the source/drain regions 110B, which includes first providing trenches 130B within ILD 101, forming the contact metal layers 116B at a bottom concave surface of trenches 130B, thereafter selectively depositing the trench liners 118B, and then depositing the contact plugs .117B within trenches 130B.

At this point, any remaining frontside and/or backside processing may be performed (not shown), such as frontside metallization/interconnect patterning. Once the frontside processing is complete, a carrier substrate may be attached to the top of the device (not shown), the device may be flipped, and the original substrate 102 may be grinded/thinned before performing backside processing (e.g., to expose the dummy contact along with any other backside connections).

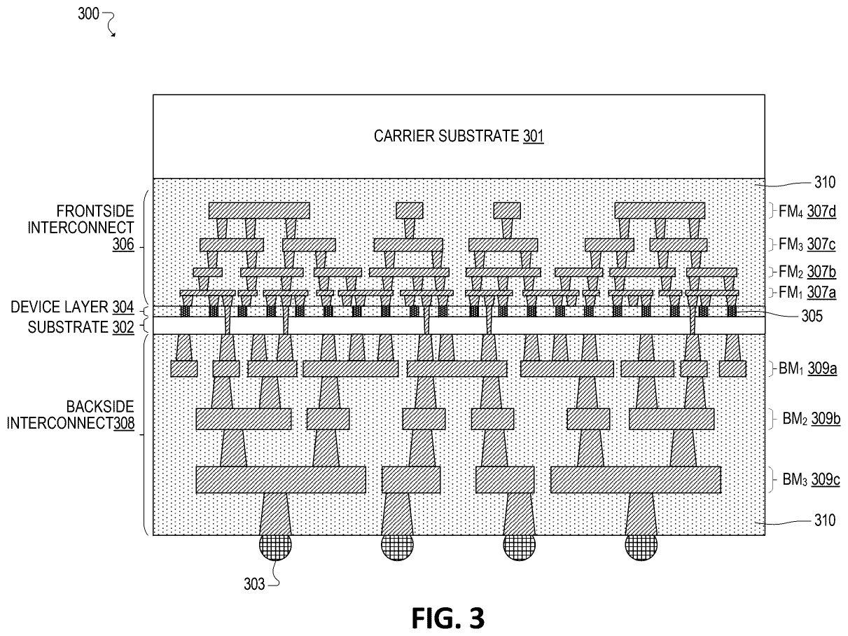

FIG. 3 illustrates a cross-section of an integrated circuit (IC) 300 with liner-last trench contacts in accordance with certain embodiments. In the illustrated embodiment, for example, IC 300 includes a layer 304 of transistors 305, and at least some of the transistors 305 have liner-last trench contacts (e.g., different contact widths and/or contact areas).

In the illustrated embodiment, IC 300 includes a thinned silicon substrate 302, a device layer 304 over the silicon substrate 302, a frontside interconnect 306 over the device layer 304, and a backside interconnect 308 under the device layer 304 and the silicon substrate 302. IC 300 also includes a carrier substrate 301 attached above the frontside interconnect 306 for structural support, along with conductive (e.g., metal) bumps 303 on the bottom surface to electrically couple IC 300 with another electronic device (e.g., an IC package, another IC die/chip, etc.).

The device layer 304 includes one or more transistors 305 and/or other semiconductor devices. Moreover, at least some of the transistors 305 have liner-last trench contacts. In some embodiments, for example, the transistors 305 may be implemented using the design of transistor 100. For example, transistors 305 may have liner-last trench contacts similar to trench contacts 112B and 114B of FIG. 1B.

The frontside interconnect 306 include multiple frontside metal (FM) layers (FM1-4) 307a-d (e.g., primarily for signaling), and the backside interconnect 308 includes multiple backside metal (BM) layers (BM1-3) 309a-c (e.g., primarily for power delivery/ground connections). The remaining areas are filled with one or more inter-layer dielectrics (ILDs) 310.

In the illustrated embodiment, the device layer 304 and interconnects 306, 308 collectively implement logic circuitry with associated power (VDD), ground (VSS), and signal networks. In some embodiments, for example, the logic circuitry may be or may include processing circuitry, memory circuitry, storage circuitry, and/or communication circuitry.

### Example Integrated Circuit Embodiments

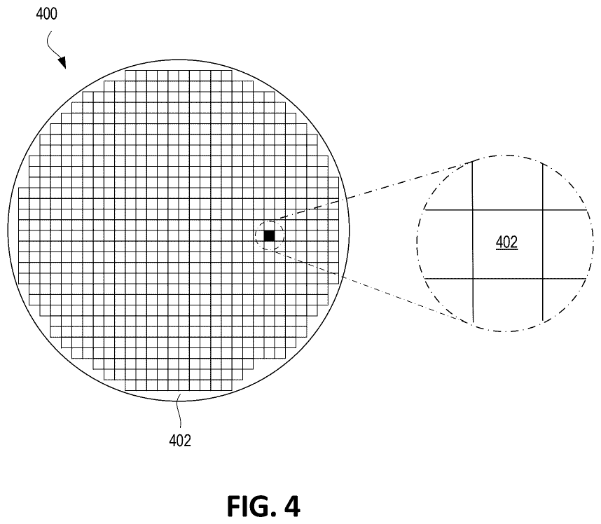

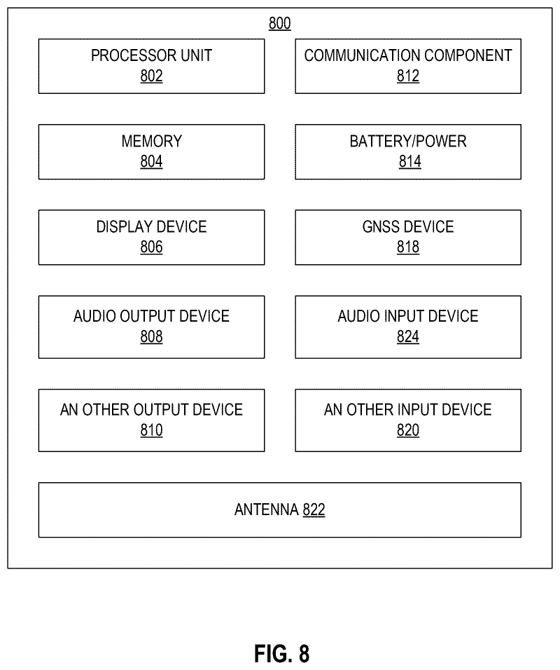

FIG. 4 is a top view of a wafer 400 and dies 402 that may be included in, or may include, any of the embodiments disclosed herein. In some embodiments, for example, the wafer 400 may include dies 402 with transistors that have liner-last trench contacts (e.g., transistor 100, IC die 300). The wafer 400 may be composed of semiconductor material and may include one or more dies 402 having integrated circuit structures formed on a surface of the wafer 400. The individual dies 402 may be a repeating unit of an integrated circuit product that includes any suitable integrated circuit. After the fabrication of the semiconductor product is complete, the wafer 400 may undergo a singulation process in which the dies 402 are separated from one another to provide discrete “chips” of the integrated circuit product. The die 402 may be any of the dies disclosed herein. The die 402 may include one or more transistors (e.g., some of the transistors 540 of FIG. 4, discussed below), supporting circuitry to route electrical signals to the transistors, passive components (e.g., signal traces, resistors, capacitors, or inductors), and/or any other integrated circuit components. In some embodiments, the wafer 400 or the die 402 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 402. For example, a memory array formed by multiple memory devices may be formed on a same die 402 as a processor unit (e.g., the processor unit 802 of FIG. 8) or other logic that is configured to store information in the memory devices or execute instructions stored in the memory array. Various ones of the microelectronic assemblies disclosed herein may be manufactured using a die-to-wafer assembly technique in which some dies are attached to a wafer 400 that include others of the dies, and the wafer 400 is subsequently singulated.

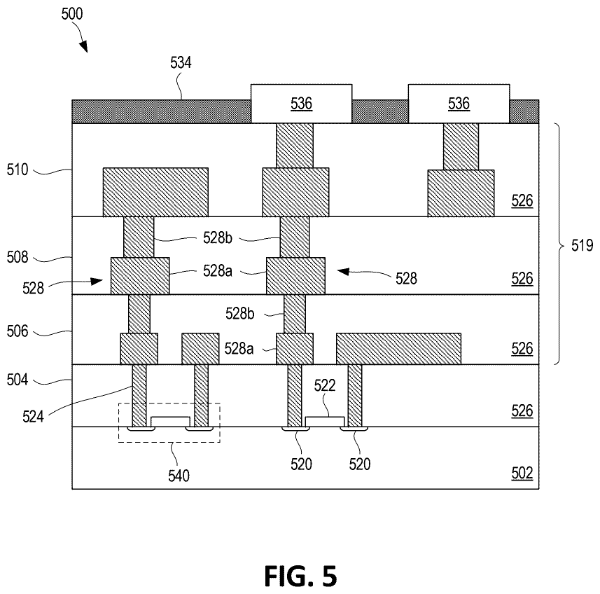

FIG. 5 is a cross-sectional side view of an integrated circuit device 500 that may be included in, or may include, any of the embodiments disclosed herein (e.g., transistor 100, IC 300). One or more of the integrated circuit devices 500 may be included in one or more dies 402 (FIG. 4). The integrated circuit device 500 may be formed on a die substrate 502 (e.g., the wafer 400 of FIG. 4) and may be included in a die (e.g., the die 402 of FIG. 4). The die substrate 502 may be a semiconductor substrate composed of semiconductor material systems including, for example, n-type or p-type materials systems (or a combination of both). The die substrate 502 may include, for example, a crystalline substrate formed using a bulk silicon or a silicon-on-insulator (SOI) substructure. In some embodiments, the die substrate 502 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 502. Although a few examples of materials from which the die substrate 502 may be formed are described here, any material that may serve as a foundation for an integrated circuit device 500 may be used. The die substrate 502 may be part of a singulated die (e.g., the dies 402 of FIG. 4) or a wafer (e.g., the wafer 400 of FIG. 4).

The integrated circuit device 500 may include one or more device layers 504 disposed on the die substrate 502. The device layer 504 may include features of one or more transistors 540 (e.g., metal oxide semiconductor field-effect transistors (MOSFETs)) formed on the die substrate 502. The transistors 540 may include, for example, one or more source and/or drain (S/D) regions 520, a gate 522 to control current flow between the S/D regions 520, and one or more S/D contacts 524 to route electrical signals to/from the S/D regions 520. The transistors 540 may include additional features not depicted for the sake of clarity, such as device isolation regions, gate contacts, and the like. The transistors 540 are not limited to the type and configuration depicted in FIG. 4 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

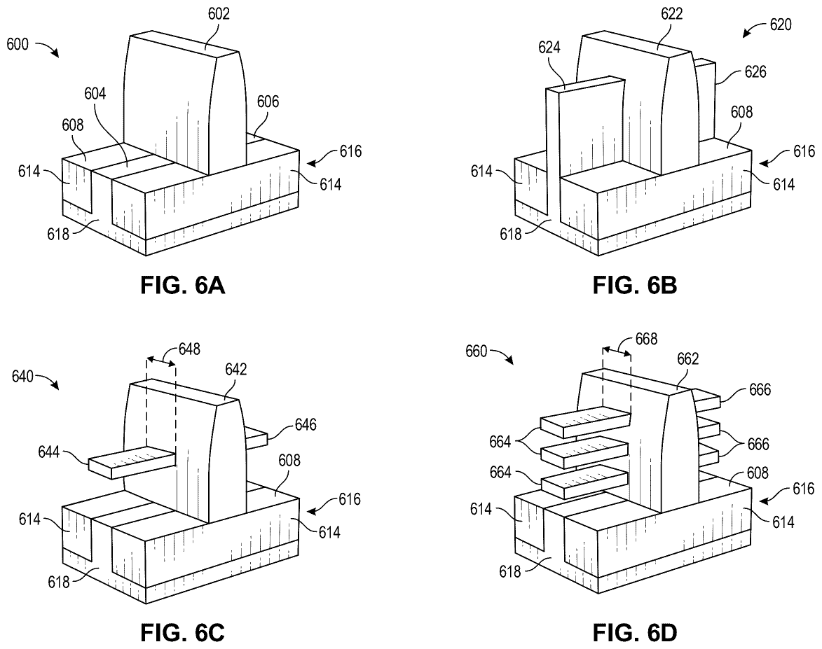

FIGS. 6A-D are simplified perspective views of example planar, FinFET, gate-all-around, and stacked gate-all-around transistors. In some embodiments, these transistors may be implemented with liner-last trench contacts (e.g., similar to transistor 100). The transistors illustrated in FIGS. 6A-6D are formed on a substrate 616 having a surface 608. Isolation regions 614 separate the source/drain regions of the transistors from other transistors and from a bulk region 618 of the substrate 616.

FIG. 6A is a perspective view of an example planar transistor 600 comprising a gate 602 that controls current flow between a source region 604 and a drain region 606. The transistor 600 is planar in that the source region 604 and the drain region 606 are planar with respect to the substrate surface 608.

FIG. 6B is a perspective view of an example FinFET transistor 620 comprising a gate 622 that controls current flow between a source region 624 and a drain region 626. The transistor 620 is non-planar in that the source region 624 and the drain region 626 comprise “fins” that extend upwards from the substrate surface 608. As the gate 622 encompasses three sides of the semiconductor fin that extends from the source region 624 to the drain region 626, the transistor 620 can be considered a tri-gate transistor. FIG. 6B illustrates one S/D fin extending through the gate 622, but multiple S/D fins can extend through the gate of a FinFET transistor.

FIG. 6C is a perspective view of a gate-all-around (GAA) transistor 640 comprising a gate 642 that controls current flow between a source region 644 and a drain region 646. The transistor 640 is non-planar in that the source region 644 and the drain region 646 are elevated from the substrate surface 608.

FIG. 6D is a perspective view of a GAA transistor 660 comprising a gate 662 that controls current flow between multiple elevated source regions 664 and multiple elevated drain regions 666. The transistor 660 is a stacked GAA transistor as the gate controls the flow of current between multiple elevated S/D regions stacked on top of each other. The transistors 640 and 660 are considered gate-all-around transistors as the gates encompass all sides of the semiconductor portions that extends from the source regions to the drain regions. The transistors 640 and 660 can alternatively be referred to as nanowire, nanosheet, or nanoribbon transistors depending on the width (e.g., widths 648 and 668 of transistors 640 and 660, respectively) of the semiconductor portions extending through the gate.

Returning to FIG. 4, a transistor 540 may include a gate 522 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 540 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 540 along the source-channel-drain direction, the gate electrode may consist of a U-shaped structure that includes a bottom portion substantially parallel to the surface of the die substrate 502 and two sidewall portions that are substantially perpendicular to the top surface of the die substrate 502. In other embodiments, at least one of the metal layers that form the gate electrode may simply be a planar layer that is substantially parallel to the top surface of the die substrate 502 and does not include sidewall portions substantially perpendicular to the top surface of the die substrate 502. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 520 may be formed within the die substrate 502 adjacent to the gate 522 of individual transistors 540. The S/D regions 520 may be formed using an implantation/diffusion process or an etching/deposition process, for example. In the former process, dopants such as boron, aluminum, antimony, phosphorous, or arsenic may be ion-implanted into the die substrate 502 to form the S/D regions 520. An annealing process that activates the dopants and causes them to diffuse farther into the die substrate 502 may follow the ion-implantation process. In the latter process, the die substrate 502 may first be etched to form recesses at the locations of the S/D regions 520. An epitaxial deposition process may then be carried out to fill the recesses with material that is used to fabricate the S/D regions 520. In some implementations, the S/D regions 520 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 520 may be formed using one or more alternate semiconductor materials such as germanium or a group III-V material or alloy. In further embodiments, one or more layers of metal and/or metal alloys may be used to form the S/D regions 520.

Electrical signals, such as power and/or input/output (I/O) signals, may be routed to and/or from the devices (e.g., transistors 540) of the device layer 504 through one or more interconnect layers disposed on the device layer 504 (illustrated in FIG. 4 as interconnect layers 506-510). For example, electrically conductive features of the device layer 504 (e.g., the gate 522 and the S/D contacts 524) may be electrically coupled with the interconnect structures 528 of the interconnect layers 506-510. The one or more interconnect layers 506-510 may form a metallization stack (also referred to as an “ILD stack”) 519 of the integrated circuit device 500.

The interconnect structures 528 may be arranged within the interconnect layers 506-510 to route electrical signals according to a wide variety of designs; in particular, the arrangement is not limited to the particular configuration of interconnect structures 528 depicted in FIG. 4. Although a particular number of interconnect layers 506-510 is depicted in FIG. 4, embodiments of the present disclosure include integrated circuit devices having more or fewer interconnect layers than depicted.

In some embodiments, the interconnect structures 528 may include lines 528a and/or vias 528b filled with an electrically conductive material such as a metal. The lines 528a may be arranged to route electrical signals in a direction of a plane that is substantially parallel with a surface of the die substrate 502 upon which the device layer 504 is formed. For example, the lines 528a may route electrical signals in a direction in and out of the page and/or in a direction across the page from the perspective of FIG. 4. The vias 528b may be arranged to route electrical signals in a direction of a plane that is substantially perpendicular to the surface of the die substrate 502 upon which the device layer 504 is formed. In some embodiments, the vias 528b may electrically couple lines 528a of different interconnect layers 506-510 together.

The interconnect layers 506-510 may include a dielectric material 526 disposed between the interconnect structures 528, as shown in FIG. 4. In some embodiments, dielectric material 526 disposed between the interconnect structures 528 in different ones of the interconnect layers 506-510 may have different compositions; in other embodiments, the composition of the dielectric material 526 between different interconnect layers 506-510 may be the same. The device layer 504 may include a dielectric material 526 disposed between the transistors 540 and a bottom layer of the metallization stack as well. The dielectric material 526 included in the device layer 504 may have a different composition than the dielectric material 526 included in the interconnect layers 506-510; in other embodiments, the composition of the dielectric material 526 in the device layer 504 may be the same as a dielectric material 526 included in any one of the interconnect layers 506-510.

A first interconnect layer 506 (referred to as Metal 1 or “M1”) may be formed directly on the device layer 504. In some embodiments, the first interconnect layer 506 may include lines 528a and/or vias 528b, as shown. The lines 528a of the first interconnect layer 506 may be coupled with contacts (e.g., the S/D contacts 524) of the device layer 504. The vias 528b of the first interconnect layer 506 may be coupled with the lines 528a of a second interconnect layer 508.

The second interconnect layer 508 (referred to as Metal 2 or “M2”) may be formed directly on the first interconnect layer 506. In some embodiments, the second interconnect layer 508 may include via 528b to couple the interconnect structures 528 of the second interconnect layer 508 with the lines 528a of a third interconnect layer 510. Although the lines 528a and the vias 528b are structurally delineated with a line within individual interconnect layers for the sake of clarity, the lines 528a and the vias 528b may be structurally and/or materially contiguous (e.g., simultaneously filled during a dual-damascene process) in some embodiments.

The third interconnect layer 510 (referred to as Metal 3 or “M3”) (and additional interconnect layers, as desired) may be formed in succession on the second interconnect layer 508 according to similar techniques and configurations described in connection with the second interconnect layer 508 or the first interconnect layer 506. In some embodiments, the interconnect layers that are “higher up” in the metallization stack 519 in the integrated circuit device 500 (i.e., farther away from the device layer 504) may be thicker that the interconnect layers that are lower in the metallization stack 519, with lines 528a and vias 528b in the higher interconnect layers being thicker than those in the lower interconnect layers.

The integrated circuit device 500 may include a solder resist material 534 (e.g., polyimide or similar material) and one or more conductive contacts 536 formed on the interconnect layers 506-510. In FIG. 4, the conductive contacts 536 are illustrated as taking the form of bond pads. The conductive contacts 536 may be electrically coupled with the interconnect structures 528 and configured to route the electrical signals of the transistor(s) 540 to external devices. For example, solder bonds may be formed on the one or more conductive contacts 536 to mechanically and/or electrically couple an integrated circuit die including the integrated circuit device 500 with another component (e.g., a printed circuit board). The integrated circuit device 500 may include additional or alternate structures to route the electrical signals from the interconnect layers 506-510; for example, the conductive contacts 536 may include other analogous features (e.g., posts) that route the electrical signals to external components. The conductive contacts 536 may serve as any of the conductive contacts described throughout this disclosure.

In some embodiments in which the integrated circuit device 500 is a double-sided die, the integrated circuit device 500 may include another metallization stack (not shown) on the opposite side of the device layer(s) 504. This metallization stack may include multiple interconnect layers as discussed above with reference to the interconnect layers 506-510, to provide conductive pathways (e.g., including conductive lines and vias) between the device layer(s) 504 and additional conductive contacts (not shown) on the opposite side of the integrated circuit device 500 from the conductive contacts 536. These additional conductive contacts may serve as any of the conductive contacts described throughout this disclosure.

In other embodiments in which the integrated circuit device 500 is a double-sided die, the integrated circuit device 500 may include one or more through silicon vias (TSVs) through the die substrate 502; these TSVs may make contact with the device layer(s) 504, and may provide conductive pathways between the device layer(s) 504 and additional conductive contacts (not shown) on the opposite side of the integrated circuit device 500 from the conductive contacts 536. These additional conductive contacts may serve as any of the conductive contacts described throughout this disclosure. In some embodiments, TSVs extending through the substrate can be used for routing power and ground signals from conductive contacts on the opposite side of the integrated circuit device 500 from the conductive contacts 536 to the transistors 540 and any other components integrated into the die 500, and the metallization stack 519 can be used to route I/O signals from the conductive contacts 536 to transistors 540 and any other components integrated into the die 500.

Multiple integrated circuit devices 500 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

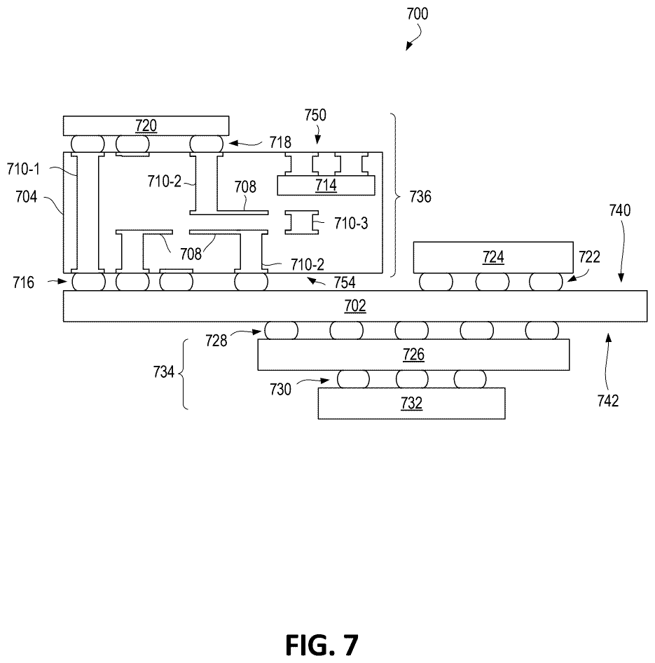

FIG. 7 is a cross-sectional side view of an integrated circuit device assembly 700 that may include any of the embodiments disclosed herein (e.g., one or more integrated circuits with transistors that have liner-last trench contacts, such as transistor 100 and IC 300). In some embodiments, the integrated circuit device assembly 700 may be a microelectronic assembly. The integrated circuit device assembly 700 includes a number of components disposed on a circuit board 702 (which may be a motherboard, system board, mainboard, etc.). The integrated circuit device assembly 700 includes components disposed on a first face 740 of the circuit board 702 and an opposing second face 742 of the circuit board 702; generally, components may be disposed on one or both faces 740 and 742. Any of the integrated circuit components discussed below with reference to the integrated circuit device assembly 700 may take the form of any suitable ones of the embodiments of the microelectronic assemblies disclosed herein.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 702. In other embodiments, the circuit board 702 may be a non-PCB substrate. The integrated circuit device assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702, and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 716 may serve as the coupling components illustrated or described for any of the substrate assembly or substrate assembly components described herein, as appropriate.

The package-on-interposer structure 736 may include an integrated circuit component 720 coupled to an interposer 704 by coupling components 718. The coupling components 718 may take any suitable form for the application, such as the forms discussed above with reference to the coupling components 716. Although a single integrated circuit component 720 is shown in FIG. 7, multiple integrated circuit components may be coupled to the interposer 704; indeed, additional interposers may be coupled to the interposer 704. The interposer 704 may provide an intervening substrate used to bridge the circuit board 702 and the integrated circuit component 720.

The integrated circuit component 720 may be a packaged or unpackaged integrated circuit product that includes one or more integrated circuit dies (e.g., the die 402 of FIG. 4, the integrated circuit device 500 of FIG. 4) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider pitch or reroute a connection to a different connection. For example, the interposer 704 may couple the integrated circuit component 720 to a set of ball grid array (BGA) conductive contacts of the coupling components 716 for coupling to the circuit board 702. In the embodiment illustrated in FIG. 7, the integrated circuit component 720 and the circuit board 702 are attached to opposing sides of the interposer 704; in other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias 710, including but not limited to through hole vias 710-1 (that extend from a first face 750 of the interposer 704 to a second face 754 of the interposer 704), blind vias 710-2 (that extend from the first or second faces 750 or 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on a first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art. In embodiments where the interposer is a non-printed circuit board

The integrated circuit device assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The integrated circuit device assembly 700 illustrated in FIG. 7 includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

FIG. 8 is a block diagram of an example electrical device 800 that may include one or more of the embodiments disclosed herein. For example, any suitable ones of the components of the electrical device 800 may include one or more integrated circuits with transistors having liner-last trench contacts (e.g., transistor 100, IC 300), integrated circuit device assemblies 700, integrated circuit components 720, integrated circuit devices 500, or integrated circuit dies 402 disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 800 can comprise one or more processor units 802 that are heterogeneous or similar to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 702.11 family), IEEE 702.16 standards (e.g., IEEE 702.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 702.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 702.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 702.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include other output device(s) 810 (or corresponding interface circuitry, as discussed above). Examples of the other output device(s) 810 may include an audio codec, a video codec, a printer, a wired or wireless transmitter for providing information to other devices, or an additional storage device.

The electrical device 800 may include other input device(s) 820 (or corresponding interface circuitry, as discussed above). Examples of the other input device(s) 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

### Example Process of Formation

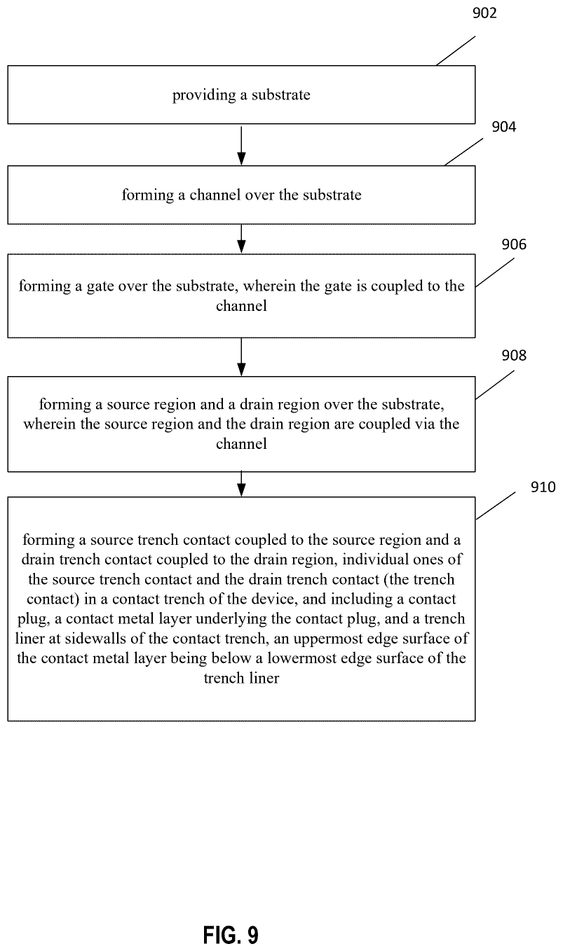

FIG. 9 illustrates a flowchart 900 for forming an integrated circuit (IC) with liner-last trench contacts in accordance with certain embodiments. It will be appreciated in light of the present disclosure that the illustrated process flow is only one example methodology for arriving at the example IC devices shown and described throughout this disclosure (e.g., transistor 100, IC 300). The operations of the illustrated process flow may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metal-organic chemical vapor deposition (MOCVD), molecular beam epitaxy (MBE), atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The illustrated process flow may be used to form one or more IC dies that respectively include a device layer along with frontside and backside interconnects above and below the device layer (e.g., for signaling and power delivery). In some embodiments, the device layer and interconnects may collectively implement logic circuitry and associated signal, power, and ground nets on the respective IC dies. Moreover, at least some of the transistors in the device layer may include liner-last trench contacts, as described throughout this disclosure.

Process 900 includes, at operation 902, providing a substrate; at operation 904, forming a channel over the substrate; at operation 906, forming a gate over the substrate, wherein the gate is coupled to the channel; at operation 908, forming a source region and a drain region over the substrate, wherein the source region and the drain region are coupled via the channel; at operation 910, forming a source trench contact coupled to the source region and a drain trench contact coupled to the drain region, individual ones of the source trench contact and the drain trench contact in a source/drain contact trench of the device, and including a contact plug, a contact metal layer below the contact plug, and a trench liner at sidewalls of the contact trench, wherein an uppermost surface of the contact metal layer is below a lowermost surface of the trench liner.

At this point, the flowchart may be complete. In some embodiments, however, the flowchart may restart and/or certain blocks may be repeated. For example, in some embodiments, the flowchart may restart at block 902 to continue forming one or more ICs with the same or similar design.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “under”, “between”, “adjacent”, “to”, and “on” as used herein may refer to a relative position of one layer or component with respect to other layers or components. For example, one layer “over”, “under”, or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views.

The term “layer” as used herein may refer to one or more layers.

The term “liner” as used herein may refer to one or more liners.

The term “package” generally refers to a self-contained carrier of one or more dice, where the dice are attached to or embedded in the package substrate, and may be encapsulated for protection, with integrated or wire-bonded interconnects between the dice, along with leads, pins, or bumps located on the external portions of the package substrate. The package may contain a single die, or multiple dice, providing respective functions. The package may be mounted on a printed circuit board for interconnection with other packaged integrated circuits and discrete components, forming a larger circuit.

The term “cored” generally refers to a substrate of an integrated circuit package built upon a board, card, or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core may allow for higher-density package architectures, as the through-vias may have relatively large dimensions and pitch compared to high-density interconnects.

The term “land side” generally refers to the side of the substrate of the integrated circuit package closest to the plane of attachment to a printed circuit board, motherboard, or other package. This is in contrast to the term “die side”, which generally refers to the side of the substrate of the integrated circuit package to which the die or dice are attached.

The terms “dielectric” and “dielectric material” generally refer to any type or number of non-electrically conductive materials. In some cases, dielectric material may be used to make up the structure of a package substrate. For example, dielectric material may be incorporated into an integrated circuit package as layers of laminate film or as a resin molded over integrated circuit dice mounted on the substrate.

The term “metallization” generally refers to metal layers formed on, over, and/or through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and may carry the same or similar meaning.

The term “bump” generally refers to a conductive layer or structure formed on a bond pad, which is typically made of solder or metal and has a round or curved shape, hence the term “bump”.

The term “substrate” generally refers to a planar platform that may include dielectric, metallization, and/or semiconductor device structures. For example, a substrate may be or may contain an integrated circuit die or may be used to fabricate an integrated circuit die. As another example, a substrate may mechanically support and electrically couple one or more IC dies on a single platform, with encapsulation of the one or more IC dies by a moldable dielectric material. A substrate may include bumps or pads as bonding interconnects on one or both sides. For example, one side of the substrate, generally referred to as the “die side”, may include bumps or pads for chip or die bonding. The opposite side of the substrate, generally referred to as the “land side”, may include bumps or pads for bonding the package to a printed circuit board.

The term “assembly” generally refers to a grouping of parts into a single functional unit. For example, certain parts may be permanently bonded together, integrated together, and/or mechanically assembled (e.g., where parts may be removable) into a functional unit.

The terms “coupled” or “connected” means a direct or indirect connection, such as a direct electrical, mechanical, magnetic, or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

### EXAMPLES

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a semiconductor device, comprising: a source region and a drain region; a source trench contact coupled to the source region and a drain trench contact coupled to the drain region, individual ones of the source trench contact and the drain trench contact in a contact trench of the device, individual ones of the source trench contact and the drain trench contact further including a contact plug, a contact metal layer below the contact plug, and a trench liner at sidewalls of the contact trench, wherein an uppermost surface of the contact metal layer is below a lowermost surface of the trench liner; a channel coupling the source region to the drain region; and a gate coupled to the channel.

Example 2 includes the subject matter of Example 1, wherein a width of the contact metal layer at its uppermost surface corresponds to a width of the contact plug at its lowermost surface.

Example 3 includes the subject matter of any one of Examples 1-2, wherein the uppermost surface of the contact metal layer is adjacent to the lowermost surface of the trench liner, defining an interface region therewith.

Example 4 includes the subject matter of Example 3, wherein a width of the contact metal layer is wider than a width of the contact plug at the interface region.

Example 5 includes the subject matter of any one of Examples 1-4, wherein the contact metal layer has a concave upper surface adjacent to a convex lower surface of the contact plug.

Example 6 includes the subject matter of any one of Examples 1-5, wherein the trench liner includes silicon, and at least one of oxygen and carbon.

Example 7 includes the subject matter of Example 6, wherein the trench liner further includes hydrogen.

Example 8 includes the subject matter of Example 7, wherein the trench liner further includes nitrogen.

Example 9 includes the subject matter of any one of Examples 1-8, wherein an interface between the contact metal layer and the contact plug includes carbon and hydrogen.

Example 10 includes the subject matter of Example 9, wherein the interface between the contact metal layer and the contact plug further includes one of sulfur, nitrogen, oxygen or phosphorus.

Example 11 includes the subject matter of Example 9, wherein the interface between the contact metal layer and the contact plug further includes oxygen and phosphorus.

Example 12 includes the subject matter of any one of Examples 1-11, wherein the semiconductor device corresponds to a nanoribbon transistor, a gate-all-around (GAA) transistor, a fin field-effect transistor (FinFET), a planar transistor, or a two-dimensional transistor.

Example 13 includes an electronic device, comprising: one or more Gate-All-Around transistors, wherein individual transistors comprise: a source region and a drain region; a source trench contact coupled to the source region and a drain trench contact coupled to the drain region, individual ones of the source trench contact and the drain trench contact in a contact trench of the device, individual ones of the source trench contact and the drain trench contact further including a contact plug, a contact metal layer below the contact plug, and a trench liner at sidewalls of the contact trench, wherein an uppermost surface of the contact metal layer is below a lowermost surface of the trench liner; a channel including a nanoribbon structure, the channel coupling the source region to the drain region; and a gate coupled to the channel.

Example 14 includes the subject matter of Example 13, wherein a width of the contact metal layer at its uppermost surface corresponds to a width of the contact plug at its lowermost surface.

Example 15 includes the subject matter of any one of Examples 13-14, wherein the uppermost surface of the contact metal layer is adjacent to the lowermost surface of the trench liner, defining an interface region therewith.

Example 16 includes the subject matter of Example 15, wherein a width of the contact metal layer is wider than a width of the contact plug at the interface region.

Example 17 includes the subject matter of any one of Examples 13-16, wherein the contact metal layer has a concave upper surface adjacent to a convex lower surface of the contact plug.

Example 18 includes the subject matter of any one of Examples 13-17, wherein the trench liner includes silicon, and at least one of oxygen and carbon.

Example 19 includes the subject matter of Example 18, wherein the trench liner further includes hydrogen.

Example 20 includes the subject matter of Example 19, wherein the trench liner further includes nitrogen.

Example 21 includes the subject matter of any one of Examples 13-20, wherein an interface between the contact metal layer and the contact plug includes carbon and hydrogen.

Example 22 includes the subject matter of Example 21, wherein the interface between the contact metal layer and the contact plug further includes at least one of sulfur, nitrogen, oxygen or phosphorus.

Example 23 includes the subject matter of Example 21, wherein the interface between the contact metal layer and the contact plug further includes oxygen and phosphorus.

Example 24 includes the subject matter of any one of Examples 13-23, wherein the individual transistors correspond to a nanoribbon transistor, a gate-all-around (GAA) transistor, a fin field-effect transistor (FinFET), a planar transistor, or a two-dimensional transistor.

Example 25 includes the subject matter of Example 13, further comprising: a circuit board; and an integrated circuit coupled to the circuit board, wherein the integrated circuit comprises processing circuitry, memory circuitry, storage circuitry, or communication circuitry, wherein one or more of the transistors are comprised in the processing circuitry, the memory circuitry, the storage circuitry, or the communication circuitry.

Example 26 includes a method of forming a semiconductor device, comprising: providing a substrate; forming a channel over the substrate; forming a gate over the substrate, wherein the gate is coupled to the channel; forming a source region and a drain region over the substrate, wherein the source region and the drain region are coupled via the channel; and forming a source trench contact coupled to the source region and a drain trench contact coupled to the drain region, individual ones of the source trench contact and the drain trench contact in a contact trench of the device, individual ones of the source trench contact and the drain trench contact further including a contact plug, a contact metal layer below the contact plug, and a trench liner at sidewalls of the contact trench, wherein an uppermost surface of the contact metal layer is below a lowermost surface of the trench liner.

Example 27 includes the subject matter of Example 26, wherein forming the source trench contact and forming the drain trench contact both include forming the trench liner after forming the contact metal layer.

Example 28 includes the subject matter of Example 26, wherein forming the trench liner includes selectively depositing the trench liner to adhere to sidewalls of the contact trench without adhering to the contact metal layer.

Example 29 includes the subject matter of Example 28, wherein selectively depositing includes applying a passivant to the contact metal layer prior to deposition of the trench liner.

Example 30 includes the subject matter of Example 29, wherein the passivant includes at least one of: one or more thiols, one or more aromatics, one or more amines, one or more alkynes, one or more nitriles, one or more phosphines, one or more phosphites, or one or more amidines.

Example 31 includes the subject matter of Example 26, wherein a width of the contact metal layer at its uppermost surface corresponds to a width of the contact plug at its lowermost surface.

Example 32 includes the subject matter of any one of Examples 26-31, wherein the uppermost surface of the contact metal layer is adjacent to the lowermost surface of the trench liner, defining an interface region therewith.

Example 33 includes the subject matter of Example 32, wherein a width of the contact metal layer is wider than a width of the contact plug at the interface region.

Example 34 includes the subject matter of any one of Examples 26-33, wherein the contact metal layer has a concave upper surface adjacent to a convex lower surface of the contact plug.

Example 35 includes the subject matter of any one of Examples 26-34, wherein the trench liner includes silicon, and at least one of oxygen and carbon.

Example 36 includes the subject matter of Example 35, wherein the trench liner further includes hydrogen.

Example 37 includes the subject matter of Example 36, wherein the trench liner further includes nitrogen.

Example 38 includes the subject matter of any one of Examples 26-37, wherein an interface between the contact metal layer and the contact plug includes carbon and hydrogen.

Example 39 includes the subject matter of Example 38, wherein the interface between the contact metal layer and the contact plug further includes one of sulfur, nitrogen, oxygen or phosphorus.

Example 40 includes the subject matter of Example 38, wherein the interface between the contact metal layer and the contact plug further includes oxygen and phosphorus.

Example 41 includes the subject matter of any one of Examples 26-40, wherein the semiconductor device corresponds to a nanoribbon transistor, a gate-all-around (GAA) transistor, a fin field-effect transistor (FinFET), a planar transistor, or a two-dimensional transistor.

1. A semiconductor device, comprising:
a source region and a drain region;
a source trench contact coupled to the source region and a drain trench contact coupled to the drain region, individual ones of the source trench contact and the drain trench contact in a contact trench of the device, individual ones of the source trench contact and the drain trench contact further including a contact plug, a contact metal layer below the contact plug, and a trench liner at sidewalls of the contact trench, wherein an uppermost surface of the contact metal layer is below a lowermost surface of the trench liner;
a channel coupling the source region to the drain region; and
a gate coupled to the channel.

2. The semiconductor device of claim 1, wherein a width of the contact metal layer at its uppermost surface corresponds to a width of the contact plug at its lowermost surface.

3. The semiconductor device of claim 1, wherein the uppermost surface of the contact metal layer is adjacent to the lowermost surface of the trench liner, defining an interface region therewith.

4. The semiconductor device of claim 3, wherein a width of the contact metal layer is wider than a width of the contact plug at the interface region.

5. The semiconductor device of claim 1, wherein the contact metal layer has a concave upper surface adjacent to a convex lower surface of the contact plug.

6. The semiconductor device of claim 1, wherein the trench liner includes silicon, and at least one of oxygen and carbon.

7. The semiconductor device of claim 6, wherein the trench liner further includes hydrogen.

8. The semiconductor device of claim 7, wherein the trench liner further includes nitrogen.

9. The semiconductor device of claim 1, wherein an interface between the contact metal layer and the contact plug includes carbon and hydrogen.

10. The semiconductor device of claim 9, wherein the interface between the contact metal layer and the contact plug further includes one of sulfur, nitrogen, oxygen or phosphorus.

11. The semiconductor device of claim 9, wherein the interface between the contact metal layer and the contact plug further includes oxygen and phosphorus.

12. The semiconductor device of claim 1, wherein the semiconductor device corresponds to a nanoribbon transistor, a gate-all-around (GAA) transistor, a fin field-effect transistor (FinFET), a planar transistor, or a two-dimensional transistor.

13. An electronic device, comprising:
one or more Gate-All-Around transistors, wherein individual transistors comprise:
a source region and a drain region;
a source trench contact coupled to the source region and a drain trench contact coupled to the drain region, individual ones of the source trench contact and the drain trench contact in a contact trench of the device, individual ones of the source trench contact and the drain trench contact further including a contact plug, a contact metal layer below the contact plug, and a trench liner at sidewalls of the contact trench, wherein an uppermost surface of the contact metal layer is below a lowermost surface of the trench liner;
a channel including a nanoribbon structure, the channel coupling the source region to the drain region; and
a gate coupled to the channel.

14. The electronic device of claim 13, wherein a width of the contact metal layer at its uppermost surface corresponds to a width of the contact plug at its lowermost surface.

15. The electronic device of claim 13, further comprising:
a circuit board; and
an integrated circuit coupled to the circuit board, wherein the integrated circuit comprises processing circuitry, memory circuitry, storage circuitry, or communication circuitry, wherein one or more of the transistors are comprised in the processing circuitry, the memory circuitry, the storage circuitry, or the communication circuitry.

16. A method of forming a semiconductor device, comprising:
providing a substrate;
forming a channel over the substrate;
forming a gate over the substrate, wherein the gate is coupled to the channel;
forming a source region and a drain region over the substrate, wherein the source region and the drain region are coupled via the channel; and
forming a source trench contact coupled to the source region and a drain trench contact coupled to the drain region, individual ones of the source trench contact and the drain trench contact in a contact trench of the device, individual ones of the source trench contact and the drain trench contact further including a contact plug, a contact metal layer below the contact plug, and a trench liner at sidewalls of the contact trench, wherein an uppermost surface of the contact metal layer is below a lowermost surface of the trench liner.

17. The method of claim 16, wherein forming the source trench contact and forming the drain trench contact both include forming the trench liner after forming the contact metal layer.

18. The method of claim 16, wherein forming the trench liner includes selectively depositing the trench liner to adhere to sidewalls of the contact trench without adhering to the contact metal layer.

19. The method of claim 18, wherein selectively depositing includes applying a passivant to the contact metal layer prior to deposition of the trench liner.

20. The method of claim 19, wherein the passivant includes at least one of: one or more thiols, one or more aromatics, one or more amines, one or more alkynes, one or more nitriles, one or more phosphines, one or more phosphites, or one or more amidines.
